(19) United States
(12) Patent Application Publication
(10) Pub. No.: US 2016/0309590 A1
(43) Pub. Date: Oct. 20, 2016

(54) APPARATUSES AND METHODS FOR A MULTI PIN-OUT SMART CARD DEVICE

(71) Applicants: HUAJIAN DING, Mianyang (CN); YING GAO, Beijing (CN); EUGENE TANG, Beijing (CN); BING HAN, Xian (CN); ZEYI LIU, Chengdu (CN); JIQIANG SONG, Beijing (CN); YUNZHEN WANG, San Jose, CA (US); DAWEI WANG, Beijing (CN); PAUL PENG, Beijing (CN)

(72) Inventors: HUAJIAN DING, Mianyang (CN); YING GAO, Beijing (CN); EUGENE TANG, Beijing (CN); BING HAN, Xian (CN); ZEYI LIU, Chengdu (CN); JIQIANG SONG, Beijing (CN); YUNZHEN WANG, San Jose, CA (US); DAWEI WANG, Beijing (CN); PAUL PENG, Beijing (CN)

(21) Appl. No.: 15/101,959

(22) PCT Filed: Jan. 6, 2014
(86) PCT No.: PCT/CN2014/070157

§ 371 Date: Jun. 6, 2016

(51) Int. Cl. H05K 1/11; H05K 7/14; H04B 1/3816; G06K 19/077

(52) U.S. Cl. CPC H05K 1/117; G06K 19/07732; H05K 7/1427; H04B 1/3816

(57) ABSTRACT

Apparatuses and a method are described. For example, an apparatus or example smart card device may comprise a casing to enclose at least a portion of a processing logic, a first plurality of contact pads disposed substantially in a row near an edge of a first side of the casing, and a second plurality of contact pads disposed in a centralized group, the second plurality of contact pads substantially separate from the first plurality of contact pads.

### TECHNICAL FIELD

Examples described herein are generally related to techniques for a smart card device, one or more host devices and a modular computing system comprising a smart card device and one or more host devices.

### BACKGROUND

Modern computing devices continue to evolve in variety of ways. One particular area in which computing devices have evolved is the number and type of devices that users rely on every day. Some devices are carried by users at all times, while other are stationary and/or are only used in specific locations or specific circumstances. These different devices also include a variety of form factors, functionality and computing capabilities. Some efforts have been made to allow for an ad hoc or other combination of devices to perform different functionality and for different uses, where multiple complete devices are utilized. These efforts, however, continue to rely on form factors that may not be desirable for some implementations, require a difficult set up process and often utilize devices that are not appropriate for an intended use. Additionally, the life cycle of modern computing devices continues to decrease as new technology and device features continue to evolve. Current devices require a complete upgrade of all device components to realize these improvements. Therefore, in some embodiments it may be desirable to have a smart card computing device that is arranged with a small and portable form factor, a variety of computing capabilities, that is capable of removably coupling with any number, type and arrangement of different host devices and is easily upgradeable without necessitating the upgrade of the host device components. It is with respect to these and other considerations that the embodiments described herein are needed.

### BRIEF DESCRIPTION OF THE DRAWINGS

FIG. 1 illustrates an embodiment of a first apparatus, a second apparatus and/or a first system.

FIG. 2 illustrates an embodiment of a second system

FIG. 3 illustrates an embodiment of a third system.

FIG. 4 illustrates an embodiment of a third apparatus.

FIG. 5 illustrates an embodiment of a fourth apparatus.

FIG. 6 illustrates an embodiment of a fifth apparatus.

FIG. 7 illustrates an embodiment of a sixth apparatus.

FIG. 8 illustrates an embodiment of a seventh apparatus.

FIG. 9 illustrates an embodiment of an eighth apparatus.

FIG. 10 illustrates an embodiment of a ninth apparatus.

FIG. 11 illustrates an embodiment of a tenth apparatus.

FIG. 12A illustrates an embodiment of an eleventh apparatus.

FIG. 12B illustrates an embodiment of a twelfth apparatus.

FIG. 13 illustrates an embodiment of a fourth system or thirteenth apparatus.

FIG. 14 illustrates an embodiment of a process flow.

### DETAILED DESCRIPTION

Embodiments are directed to casings and contact pad configurations for a card device. Some embodiments are particularly directed to an apparatus comprising a card device, the smart card device comprising processing logic and one or more processor circuits, an interface coupled to the one or more processor circuits, the smart card device sized to be removably inserted into a host device and the interface configured to removably couple the smart card device to the host device, and logic, at least a portion of which is in hardware, the logic to configure the smart card device based on one or more characteristics of the host device.

A computer generally includes at least a processor (which may also be referred to as a processing circuit, processing logic, processing core(s), etc.) and an input/output interface. These ingredients also are usually in place in embedded systems. The processor is generally coupled to some form of a “circuit board.” The board will allow the processor to be communicatively coupled to external peripherals by having I/O pins/lines that are exposed to the peripherals on the board.

This board may take one of many forms. With an embedded system, the form factor of the board may have quite a small size requirement. In many embodiments described, a Secure Digital (SD) card device format is utilized as the form factor of choice for the processor and board of the described system. In other embodiments, other small card devices may be utilized, such as a mini-SD card device, a micro-SD card device, a Subscriber Identity Module (SIM) card, or one of many other small card device form factors. Other embodiments may utilize variations of high speed SD, such as UHS-II pins and sockets.

In some embodiments, the board will include a standard set of contact pads for the given form factor (e.g., an SD card will include a set of SD card contact pads (i.e., pins)). Yet, in many other embodiments, the board will have additional contact pads apart from the standard set of contact pads. For example, in some embodiments, a set of SIM card contact pads are also present on the SD card form factor board to allow for pin compatibility in a SIM socket in addition to pin compatibility in an SD socket. Apart from compatibility with multiple sockets, a board that includes I/O pin outs of both SD pins and SIM pins together could utilize an additional set of I/O pins (i.e. contact pads) for simultaneous I/O communication on more pins. Other multi-pin out configurations may be utilized, such as a micro-SD card pin out combined with a SIM card pin out on the board form factor. Custom pin outs may also be utilized, including a standard pin out combined with additional custom pins.

It should be noted that a contact pad may be any standard form of pad, socket, pin, or other communicable coupling of I/O electrical contacts from one device to a second device. Each I/O electrical contact electrically couples through a mechanical means an I/O trace on a host device to a contact pad on a card device. For example, in many embodiments, a standard SD card contact pad will comprise a gold-plated pad that electrically couples a wire trace placed within the board underneath to an electrical contact in a host device that the card device is inserted into. A basic mechanical means of creating and keeping the contact from the host device can be utilized and may include springs, cantilevers, pressure contacts, etc.

In many embodiments, the pin configuration is programmable by logic on the board or elsewhere. The pin out on the board may not be hardwired, but dynamically programmable and changeable from a central logic. One card device may be backward compatible across several slots/sockets. For example, the card device can have additional SIM pins and UHS-II pins, but will still function in a low-speed SD socket (without the ability to deal with the extra pins on the card device). In this case, only a small number of low-speed SD pins would be operational, but the card device can still work on a limited number of pins. For example, a card device in a low-speed SD socket with the generic SD pins only may allow serial peripheral interface (SPI) pins, but may not allow for general purpose I/O (GPIO) pins at the same time.

The multi-pin out configuration may allow this small form factor card device to be beneficial to many users of modern computing devices that typically own a variety of different devices used for different purposes, at different times, in different locations, etc. For example, a typical user may utilize a smartphone, a tablet computer, a laptop computer, a smartwatch or other wearable computing device, a smart speaker or audio/video (A/V) system, a smart remote control and the like. The embodiments are not limited to the number or type of devices described herein. In some embodiments, each of these devices may comprise a completely separate and independent device. For example, each device may include its own processor, memory, power supply/source and the like. In these embodiments, it may be cumbersome for a user to remember and/or carry all of the devices that they need. Additionally, as upgrades become available for any particular component or particular device, it is currently not possible to upgrade only portions of each device. Rather, a user is forced to completely replace any given device to realize the advantages of any available upgrades.

The plurality of devices described above may also present users with the additional problem of synchronizing all of their data across the different devices. Cloud-based services have attempted to solve these and other problems, but these services can be slow and, sometimes, less than trustworthy. Dock-based local synchronization solutions have also been attempted but these solutions can be too ad hoc and thus inconvenient, difficult to use, etc. The amount of data that is synchronized by these conventional approaches tends to be very limited.

Some current solutions attempt to combine a plurality of complete and separate devices in different ways to realize the benefits of certain devices and to attempt to overcome the shortcomings of other devices. For example, a user may attempt to use a smart phone to replace a smart remote control device. While this solution may enable remote control functionality on a smartphone, this solution may be overkill as a typical smartphone may be much more powerful and may use much more power than is needed to operate a satisfactory remote control device. Additionally, the interface may not be suitable for use as a remote control device because the smartphone was not designed with that use in mind.

In other embodiments it may be desirable to combine devices to take advantage of the capabilities of one device that may be lacking or non-existent on another device. For example, it may be desirable to combine a smartphone with a display device and/or a keyboard due to the size limitations of the display and input limitations of a typical smartphone, or to combine a smartphone with a smart speaker due to the audio limitations associated with a smartphone form factor. Current solutions to forming these combinations may include docking (wired and/or wireless), Bluetooth connections, etc. for example. In these embodiments, a first device may be associated with a second device via a wireless pairing procedure or via a physical coupling (e.g. via a cable or a physical dock) of the devices. These combinations may be cumbersome, difficult to establish and may introduce even more devices (e.g. a dock or cable) into the list of already excessive devices that a user may need to own/have available.

In still other embodiments some current devices may be designed to be operative in a number of different configurations and/or form factors. For example, a laptop computer may be designed such that the display is removable for operation as a tablet computing device. These embodiments, while a potential improvement over previous designs, still include many of the shortcomings described above. Additionally, none of the above-described current combination of devices solves the upgrade problem described above. For example, because the pace of today's technology advancement is rapid and new generations of hardware devices rapidly appear, one may be forced into upgrading devices wholesale, throwing away perfectly good components such as touch displays in these existing solutions.

It is with respect to these and other considerations that the embodiments described herein are needed. In some embodiments, a computing device may be decomposed into two main components: a compact “skin core” or smart card device and a “skin” or host device. In various embodiments, while not limited in this respect, the smart card device may be arranged to have a size similar to that of an SD card or a credit card. The smart card device may comprise, among other components, one or more processor circuits, memory, stable storage, one or more communication modules, a power source/supply and components capable of driving one or more input/output (I/O) peripherals (e.g. USB ports, a module that drives a touch display, modules for audio input and output, etc.). In some embodiments, a host device may comprise a number of I/O mechanisms that interact with a human user directly, such as a touch display and a speaker. As described herein, the smart card device may be arranged to be easily and removably detached (or unplugged) from one host device and re-inserted into a different host device.

In some examples, a user may choose to carry a compact smart card device with her, which can be a “naked” smart card device carried in a wallet or inserted into a portable host device such as a wearable device. At a later time or at a different location, the user may take out the smart card device from its current resting place and plug it into a different host device. The number, type and arrangement of host devices may be limitless as a plurality of host devices may be available for different occasions, environments, and special purposes. Some example host devices include but are not limited to a universal television (TV) touch display remote (which, in addition to simulating buttons on a traditional remote, may have sophisticated functionalities such as video thumbnails for a smart TV's channels), a wearable computing device such as a smartwatch (which, while displaying current time most of the time, could also run apps made for the smartwatch), a projector (such as a pico-projector), a flexible (rollable) display, a smart speaker, etc.

In various embodiments, decomposing a system into these discrete components may allow a user to upgrade the smart card device and the host device separately. Additionally, a compact smart card device may allow a user to carry her data, her programs, and her settings with her at all times and the user may choose the most appropriate host device to couple with her smart card device at different places and different times. In various embodiments, in addition to the advantage of separately upgrading the smart card device and the host device, other advantages may additionally be realized by separating the components of the smart card device and the host device. For example, the lack peripherals associated with a smart card device may be a blessing in that it may help to keep the smart card device small, cheap, extremely portable, versatile, and flexible as it is not permanently tied to interface peripherals that are of fixed sizes or fixed functionalities and can be too limiting for particular occasions and uses. Other embodiments are described and claimed.

With general reference to notations and nomenclature used herein, the detailed description that follows may be presented in terms of program procedures executed on a computer or network of computers. These procedural descriptions and representations are used by those skilled in the art to most effectively convey the substance of their work to others skilled in the art.

A procedure is here and is generally conceived to be a self-consistent sequence of operations leading to a desired result. These operations are those requiring physical manipulations of physical quantities. Usually, though not necessarily, these quantities take the form of electrical, magnetic or optical signals capable of being stored, transferred, combined, compared, and otherwise manipulated. It proves convenient at times, principally for reasons of common usage, to refer to these signals as bits, values, elements, symbols, characters, terms, numbers, or the like. It should be noted, however, that all of these and similar terms are to be associated with the appropriate physical quantities and are merely convenient labels applied to those quantities.

Further, the manipulations performed are often referred to in terms, such as adding or comparing, which are commonly associated with mental operations performed by a human operator. No such capability of a human operator is necessary, or desirable in most cases, in any of the operations described herein that form part of one or more embodiments. Rather, the operations are machine operations. Useful machines for performing operations of various embodiments include general-purpose digital computers or similar devices.

Various embodiments also relate to apparatus or systems for performing these operations. This apparatus may be specially constructed for the required purpose or it may comprise a general-purpose computer as selectively activated or reconfigured by a computer program stored in the computer. The procedures presented herein are not inherently related to a particular computer or other apparatus. Various general-purpose machines may be used with programs written in accordance with the teachings herein, or it may prove convenient to construct more specialized apparatus to perform the required method steps. The required structure for a variety of these machines will appear from the description given.

Reference is now made to the drawings, wherein like reference numerals are used to refer to like elements throughout. In the following description, for purposes of explanation, numerous specific details are set forth in order to provide a thorough understanding thereof. It may be evident, however, that the novel embodiments can be practiced without these specific details. In other instances, well-known structures and devices are shown in block diagram form in order to facilitate a description thereof. The intention is to cover all modifications, equivalents, and alternatives consistent with the claimed subject matter.

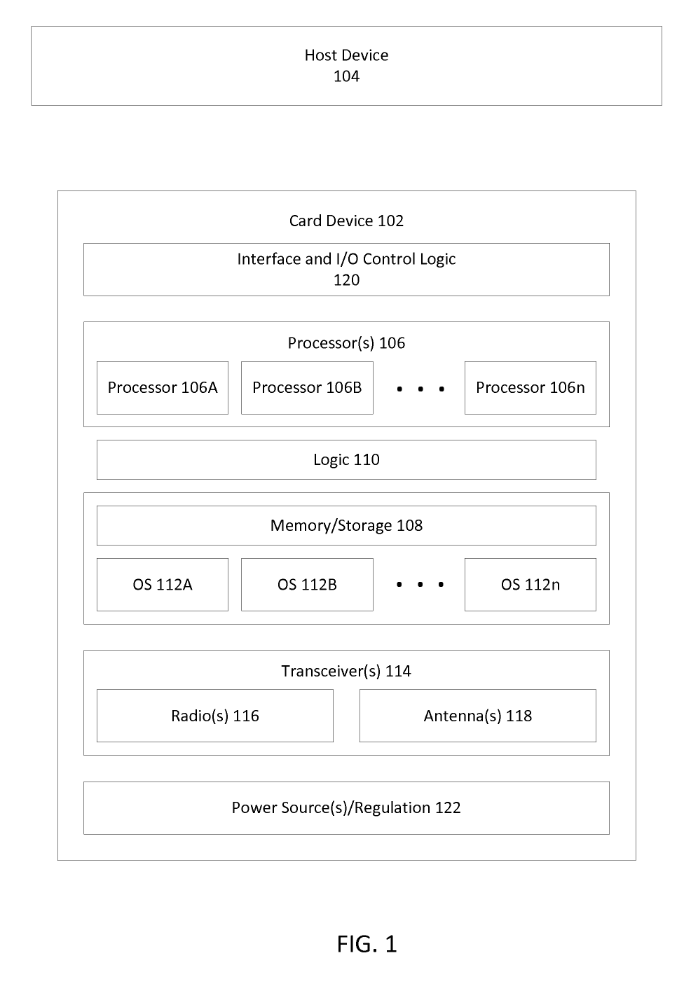

FIG. 1 illustrates a block diagram for a system 100 or an apparatus 100. In one embodiment, the system or apparatus 100 (referred to hereinafter as system 100) may comprise a computer-based system comprising an apparatus 102 and an apparatus 104. In some embodiments, apparatus 102 may comprise a smart card device 102 and apparatus 104 may comprise a host device 104. While referred to hereinafter as a smart card device 102 and a host device 104 for purposes of simplicity and illustration, it should be understood that the devices 102, 104 may comprise any suitable name, label, configuration and/or form factor and still fall within the described embodiments.

The smart card device 102 may comprise a device having a compact form factor arranged to support a number of computing components. As described herein, a smart card, chip card, or integrated circuit card (ICC) device may comprise any pocket-sized or portable card with embedded integrated circuits or other computing components. In some embodiments, the smart card device 102 may be sized and shaped similar to a Secure Digital (SD) card, a mini SD card, a micro SD card, a Subscriber Identity Module (SIM) card, a credit card or other suitable portable and compact form factor. While described herein as having a particular shape or size, one skilled in the art will understand that the embodiments are not limited in this respect.

The smart card device 102 may comprise, for example, one or more processor circuits 106 (also referred to as processor logic(s), processor core(s), etc.) (e.g. processor 106A, processor 106B, and processors through processor 106n (where n is the total number of processors)), memory 108, logic 110, OS(s) 112 (e.g. OS 112A and OS 112B, and OSs through OS 112m (where m is the total number of OSs)), transceiver 114, radio(s) 116, antenna(s) 118 interface and I/O (input/output) control logic (IICL) 120, and power source/regulation 122. Although the smart card device 102 shown in FIG. 1 has a limited number of elements in a certain topology, it may be appreciated that the smart card device 102 may include more or less elements in alternate topologies as desired for a given implementation.

In various embodiments, smart card device may comprise a processor circuit 106. The processor circuit 106 can be any of various commercially available processors, including without limitation an AMD® Athlon®, Duron® and Opteron® processors; ARM® application, embedded and secure processors; IBM® and Motorola® DragonBall® and PowerPC® processors; IBM and Sony® Cell processors; Intel® Celeron®, Core (2) Duo®, Core (2) Quad®, Core i3®, Core i5®, Core i7®, Atom®, Itanium®, Pentium®, Xeon®, andXScale® processors; and similar processors. Dual microprocessors, multi-core processors, and other multi-processor architectures may also be employed as the processor circuit 106.

As shown in FIG. 1, in some embodiments smart card device 102 may comprise two processor circuits 106A and 106B, or comprise any number of processor circuits. In other embodiments, the processor circuits 106A, 106B, 106n may comprise separate cores of a multi-core processor 106. The embodiments are not limited in this respect.

In some embodiments, the one or more processor circuits 106A, 106B may comprise a first processor circuit 106A arranged to execute a first operating system 112A and a second processor circuit 106B arranged to execute a second operating system 112B (and potentially any number of additional operating systems n being executed on additional processor circuits). In various embodiments, the logic 110 may be operative to automatically select one of the first processor circuit 106A and first operating system 112A or second processor circuit 106B and second operating system 112B based on the one or more characteristics of the host device 104 as described in more detail below.

The first processor circuit 106A may operate at a first frequency and the second processor circuit 106B may operate at a second frequency less than the first frequency in some embodiments. For example, the first processor circuit 106A may comprise a central processing unit (CPU) capable of executing a full featured operating system 112A, such as an Android operating system, iOS operating system, OS X operating system, Linux operating system, Windows operating system or any other suitable operating system. Processor circuit 106B, on the other hand, may comprise a low power, low frequency processor circuit such a microcontroller (MCU) or the like. Processor circuit 106B may be operative to execute a boot OS, real-time OS (RTOS), run-time OS or limited functionality OS 112B that is designed for a specific purpose, application or device. The embodiments are not limited in this respect.

In various embodiments, smart card device 102 may comprise or include a memory unit 108. The memory unit 108 may store, among other types of information, logic 110 and OS 112A, OS 112B, etc. The memory unit 108 may include various types of computer-readable storage media in the form of one or more higher speed memory units, such as read-only memory (ROM), random-access memory (RAM), dynamic RAM (DRAM), Double-Data-Rate DRAM (DDRAM), synchronous DRAM (SDRAM), static RAM (SRAM), programmable ROM (PROM), erasable programmable ROM (EPROM), electrically erasable programmable ROM (EEPROM), flash memory, polymer memory such as ferroelectric polymer memory, ovonic memory, phase change or ferroelectric memory, silicon-oxide-nitride-oxide-silicon (SONOS) memory, magnetic or optical cards, an array of devices such as Redundant Array of Independent Disks (RAID) drives, solid state memory devices (e.g., USB memory, solid state drives (SSD) and any other type of storage media suitable for storing information. While shown as being included with memory 108 in FIG. 1, it should be understood that logic 110 and/or OS 112A, 112B may be located elsewhere within smart card device 102 and still fall within the described embodiments.

In some embodiments, smart card device 102 may comprise logic 110. Examples of logic 110 may include but are not limited to executable computer program instructions implemented using any suitable type of code, such as source code, compiled code, interpreted code, executable code, static code, dynamic code, object-oriented code, visual code, and the like. Embodiments may also be at least partly implemented as instructions contained in or on a non-transitory computer-readable medium, which may be read and executed by one or more processors to enable performance of the operations described herein. In some embodiments, at least a portion of logic 110 is implemented in hardware. Other embodiments are described and claimed.

Smart card device 102 may comprise a power source and/or power regulation(PSPR) 122 in various embodiments. In some embodiments, PSPR 112 may comprise a battery such as a lithium ion battery or the like. In some embodiments, PSPR also may include one or more voltage regulators to regulate the voltage supplied by the power source. PSPR 122 may be operative to provide power to one or more of the components of smart card device 102 and may additionally be operative to provide power to one or more of I/O devices of host device 104 when the smart card device 102 and host device 104 are coupled together as described in more detail below. The embodiments are not limited in this respect.

In various embodiments, smart card device 102 may include an interface and I/O control logic (IICL) 120. IICL 120 may comprise a plurality of input/output (I/O) pins or ports in some embodiments. For example, the IICL 120 may be operative to removably and communicatively couple smart card device 102 with host device 104 via corresponding interface 130. In various embodiments, the IICL 120 may be operative to enable or arranged to support plug and play operation between the smart card device 102 and a plurality of host devices. In other embodiments, the IICL 120 may enable or support hot swapping or hot plugging of the smart card device 102 with a plurality of host devices.

Additionally, IICL 120 may also include logic that could be software logic, hardware logic, or a combination of both that dynamically configures the interface of card device 102 to interface correctly with one of a number of host devices 104. The pin out of card device 102 (described in detail below) is not hardwired in many embodiments and instead can be programmed according to the interface the card device 102 is plugged into. This dynamic programmability may be based on a discovery protocol that determines the pin out of the host device 104 interface upon being plugged in. For example, one or more pins may be set to correspond discovery information for the plurality of other available pins in the interface. Once the IICL 120 retrieves this information, it may program the capabilities of all pins on the card device 102 for further interface compatibility with the host device 104. In other embodiments, each pin on the card device 102 may check for a live link to determine which pins are available for interfacing.

Because this is a dynamic configuration, the device pins may change functionality and/or operational state depending on the type of host device 104 interface available. The functionality of a given pin may even change while maintaining a plugged in state with a single host device 104 in some embodiments. Other embodiments are described and claimed.

Smart card device 102 may comprise one or more wireless transceivers 114 in some embodiments. Each of the wireless transceivers 114 may be implemented as physical wireless adapters or virtual wireless adapters sometimes referred to as “hardware radios” and “software radios.” In the latter case, a single physical wireless adapter may be virtualized using software into multiple virtual wireless adapters. A physical wireless adapter typically connects to a hardware-based wireless access point. A virtual wireless adapter typically connects to a software-based wireless access point, sometimes referred to as a “SoftAP.” For instance, a virtual wireless adapter may allow ad hoc communications between peer devices, such as a smart phone and a desktop computer or notebook computer. Various embodiments may use a single physical wireless adapter implemented as multiple virtual wireless adapters, multiple physical wireless adapters, multiple physical wireless adapters each implemented as multiple virtual wireless adapters, or some combination thereof. The embodiments are not limited in this case.

The wireless transceivers 114 may comprise or implement various communication techniques to allow the smart card device 102 to communicate with other electronic devices. For instance, the wireless transceivers 114 may implement various types of standard communication elements designed to be interoperable with a network, such as one or more communications interfaces, network interfaces, network interface cards (NIC), radios, wireless transmitters/receivers (transceivers), wired and/or wireless communication media, physical connectors, and so forth. By way of example, and not limitation, communication media includes wired communications media and wireless communications media. Examples of wired communications media may include a wire, cable, metal leads, printed circuit boards (PCB), backplanes, switch fabrics, semiconductor material, twisted-pair wire, co-axial cable, fiber optics, a propagated signal, and so forth. Examples of wireless communications media may include acoustic, radio-frequency (RF) spectrum, infrared and other wireless media.

In various embodiments, the smart card device 102 may implement different types of wireless transceivers 114. Each of the wireless transceivers 114 may implement or utilize a same or different set of communication parameters to communicate information between various electronic devices. In one embodiment, for example, each of the wireless transceivers 114 may implement or utilize a different set of communication parameters to communicate information between smart card device 102 and any number of other devices. Some examples of communication parameters may include without limitation a communication protocol, a communication standard, a radio-frequency (RF) band, a radio, a transmitter/receiver (transceiver), a radio processor, a baseband processor, a network scanning threshold parameter, a radio-frequency channel parameter, an access point parameter, a rate selection parameter, a frame size parameter, an aggregation size parameter, a packet retry limit parameter, a protocol parameter, a radio parameter, modulation and coding scheme (MCS), acknowledgement parameter, media access control (MAC) layer parameter, physical (PHY) layer parameter, and any other communication parameters affecting operations for the wireless transceivers 114. The embodiments are not limited in this context.

In various embodiments, the wireless transceivers 114 may implement different communication parameters offering varying bandwidths, communications speeds, or transmission range. For instance, a first wireless transceiver may comprise a short-range interface implementing suitable communication parameters for shorter range communications of information, while a second wireless transceiver may comprise a long-range interface implementing suitable communication parameters for longer range communications of information.

In various embodiments, the terms “short-range” and “long-range” may be relative terms referring to associated communications ranges (or distances) for associated wireless transceivers 114 as compared to each other rather than an objective standard. In one embodiment, for example, the term “short-range” may refer to a communications range or distance for the first wireless transceiver that is shorter than a communications range or distance for another wireless transceiver 114 implemented for the smart card device 102, such as a second wireless transceiver. Similarly, the term “long-range” may refer to a communications range or distance for the second wireless transceiver that is longer than a communications range or distance for another wireless transceiver 114 implemented for the smart card device 102, such as the first wireless transceiver. The embodiments are not limited in this context.

In various embodiments, the terms “short-range” and “long-range” may be relative terms referring to associated communications ranges (or distances) for associated wireless transceivers 114 as compared to an objective measure, such as provided by a communications standard, protocol or interface. In one embodiment, for example, the term “short-range” may refer to a communications range or distance for the first wireless transceiver that is shorter than 300 meters or some other defined distance. Similarly, the term “long-range” may refer to a communications range or distance for the second wireless transceiver that is longer than 300 meters or some other defined distance. The embodiments are not limited in this context.

In one embodiment, for example, the wireless transceiver 114 may comprise a radio designed to communicate information over a wireless personal area network (WPAN) or a wireless local area network (WLAN). The wireless transceiver 180-1 may be arranged to provide data communications functionality in accordance with different types of lower range wireless network systems or protocols. Examples of suitable WPAN systems offering lower range data communication services may include a Bluetooth system as defined by the Bluetooth Special Interest Group, an infra-red (IR) system, an Institute of Electrical and Electronics Engineers (IEEE) 802.15 system, a DASH7 system, wireless universal serial bus (USB), wireless high-definition (HD), an ultra-side band (UWB) system, and similar systems. Examples of suitable WLAN systems offering lower range data communications services may include the IEEE 802.xx series of protocols, such as the IEEE 802.11a/b/g/n series of standard protocols and variants (also referred to as “WiFi”). It may be appreciated that other wireless techniques may be implemented, and the embodiments are not limited in this context.

In one embodiment, for example, the wireless transceiver 114 may comprise a radio designed to communicate information over a wireless local area network (WLAN), a wireless metropolitan area network (WMAN), a wireless wide area network (WWAN), or a cellular radiotelephone system. Another wireless transceiver may be arranged to provide data communications functionality in accordance with different types of longer range wireless network systems or protocols. Examples of suitable wireless network systems offering longer range data communication services may include the IEEE 802.xx series of protocols, such as the IEEE 802.11a/b/g/n series of standard protocols and variants, the IEEE 802.16 series of standard protocols and variants, the IEEE 802.20 series of standard protocols and variants (also referred to as “Mobile Broadband Wireless Access”), and so forth. Alternatively, the wireless transceiver 180-2 may comprise a radio designed to communication information across data networking links provided by one or more cellular radiotelephone systems. Examples of cellular radiotelephone systems offering data communications services may include GSM with General Packet Radio Service (GPRS) systems (GSM/GPRS), CDMA/1×RTT systems, Enhanced Data Rates for Global Evolution (EDGE) systems, Evolution Data Only or Evolution Data Optimized (EV-DO) systems, Evolution For Data and Voice (EV-DV) systems, High Speed Downlink Packet Access (HSDPA) systems, High Speed Uplink Packet Access (HSUPA), and similar systems. It may be appreciated that other wireless techniques may be implemented, and the embodiments are not limited in this context.

Although not shown, smart card device 102 may further comprise one or more device resources commonly implemented for electronic devices, such as various computing and communications platform hardware and software components typically implemented by a personal electronic device. Some examples of device resources may include without limitation a co-processor, a graphics processing unit (GPU), a chipset/platform control hub (PCH), an input/output (I/O) device, computer-readable media, network interfaces, location devices (e.g., a GPS receiver), sensors (e.g., biometric, thermal, environmental, proximity, accelerometers, barometric, pressure, etc.), portable power supplies (e.g., a battery), application programs, system programs, and so forth. The embodiments, however, are not limited to these examples.

In the illustrated embodiment shown in FIG. 1, the processor(s) 106 may be communicatively coupled to one or more of the memory 108, logic 110, power source 112, transceiver 114, radio 116, antenna 118 and/or interface 120. The memory unit 108 may store the logic 110 arranged for execution by the processor 106 to enable processing capabilities. The logic 110 may generally provide features to enable any of the functionality described herein. Other embodiments are described and claimed.

The host device 104 may comprise, for example, an interface and I/O devices. In some embodiments, the I/O devices may include but are not limited to display, speaker, microphone, projector, camera, keyboard, one or more additional input devices (such as a touchpad, touchscreen), and one or more sensors (such as an accelerometer, gyroscope, global positioning system (GPS) logic, Infrared motion detector, etc.). Although the host device 104 shown in FIG. 1 has a limited number of elements in a certain topology, it may be appreciated that the host device 104 may include more or less elements in alternate topologies as desired for a given implementation. For example, any number, type or arrangement of an I/O device, including devices not shown in FIG. 1, could be used and still fall within the described embodiments.

The one or more I/O devices may be arranged to provide functionality to the host device 104 and/or the smart card device 102 including but not limited to capturing images, exchanging information, capturing or reproducing multimedia information, receiving user feedback, or any other suitable functionality. Non-limiting examples of input/output devices include a camera, QR reader/writer, bar code reader, buttons, switches, input/output ports such as a universal serial bus (USB) port, touch-sensitive sensors, pressure sensors, a touch-sensitive digital display and the like. The embodiments are not limited in this respect.

The host device 104 may comprise one or more displays in some embodiments. The displays may comprise any digital display device suitable for an electronic device. For instance, the displays may be implemented by a liquid crystal display (LCD) such as a touch-sensitive, color, thin-film transistor (TFT) LCD, a plasma display, a light emitting diode (LED) display, an organic light emitting diode (OLED) display, a cathode ray tube (CRT) display, or other type of suitable visual interface for displaying content to a user of the host device 104 when used in connection with the smart card device 102. The displays may further include some form of a backlight or brightness emitter as desired for a given implementation.

In various embodiments, the displays may comprise touch-sensitive or touchscreen displays. A touchscreen may comprise an electronic visual display that is operative to detect the presence and location of a touch within the display area or touch interface. In some embodiments, the display may be sensitive or responsive to touching of the display of the device with a finger or hand. In other embodiments, the display may be operative to sense other passive objects, such as a stylus or electronic pen. In various embodiments, displays may enable a user to interact directly with what is displayed, rather than indirectly with a pointer controlled by a mouse or touchpad. Other embodiments are described and claimed.

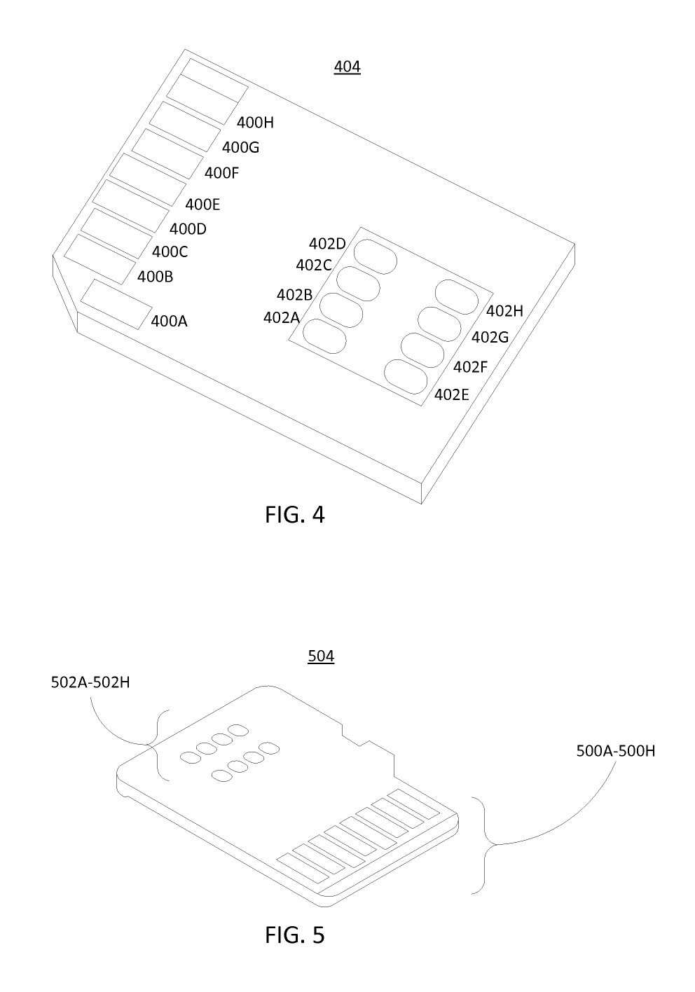

In some embodiments, host device 104 may comprise an enclosure to support the one or more (I/O) devices. The enclosure may comprise any suitable case or other structure arranged to support the I/O devices and to removably receive a smart card device 102. For example, the enclosure may be sized and shaped like a smart remote control device, a smart watch, a digital display, a television, a printer, a speaker, a telephone, a smartphone, etc. There is no limit on the size, shape or arrangement of the enclosure as described herein. In various embodiments, the enclosure may comprise an opening to receive and support the smart card device 102. For example, the opening may be sized and shaped to accommodate the size of smart card device 102 as shown and described in more details with reference to FIGS. 3 and 4.

While not limited in this respect, in some embodiments the host device may comprise one or more of a wearable device, a control device, a display device, an audio/video (A/V) device, a toy device such as a remote control car or a robot device. For example, the host device may comprise a smartwatch device, a TV remote control device, a smart speaker, etc. One skilled in the art will understand that any suitable device could be arranged as a host device 104 to accommodate smart card device 102 and, as such, the embodiments are not limited to the examples described herein.

In some embodiments, the host device 104 may comprise a dumb device. More particularly, the host device itself may not include components as shown in FIG. 1 as forming part of smart card device 102. For example, host device 104 may not include its own processor, memory, power source, transceiver, etc. Instead, the host device 104 may rely on a smart card device like smart card device 102 for power and processing capabilities. In this manner, any number of host devices could be produced inexpensively and each could be powered and provided with computing capabilities by a common smart card device. In some embodiments, for example, the one or more I/O devices of host device 104 may be operative to receive power from power source 122 of smart card device 102. Similarly, the one or more I/O devices 140 may be controlled by I/O logic 110 of the smart card device 102. Other embodiments are described and claimed. While not shown herein, in some embodiments the host device may include or comprise an independent power supply (e.g. separate and distinct from the power supply of the smart card device) that may power one or more of the components of the host device 104 and/or one or more components of the smart card device 102. Other embodiments are described and claimed.

Host device 104 may comprise an interface to removably couple the host device 104 to a smart card device 102 sized to be removably inserted into an opening of the enclosure of the host device 104 in some embodiments. For example, the host device interface may correspond, mate and/or couple with the interface 120 of smart card device 120 in some embodiments. In various embodiments, the interface 120 may include one or more male pins or ports and the host device interface may include corresponding female pins or ports, or vice versa. The embodiments are not limited in this respect.

Although not shown, some example systems utilizing card device 102 and host device 104 may include a smart card device and a plurality of host devices. Smart card device 102 may be removably coupled with and/or inserted into one or more of a remote control device, a smart watch, a projector, a display or TV, and/or a smart speaker 210. One skilled in the art will appreciate that the embodiments are not limited to the types of host devices described.

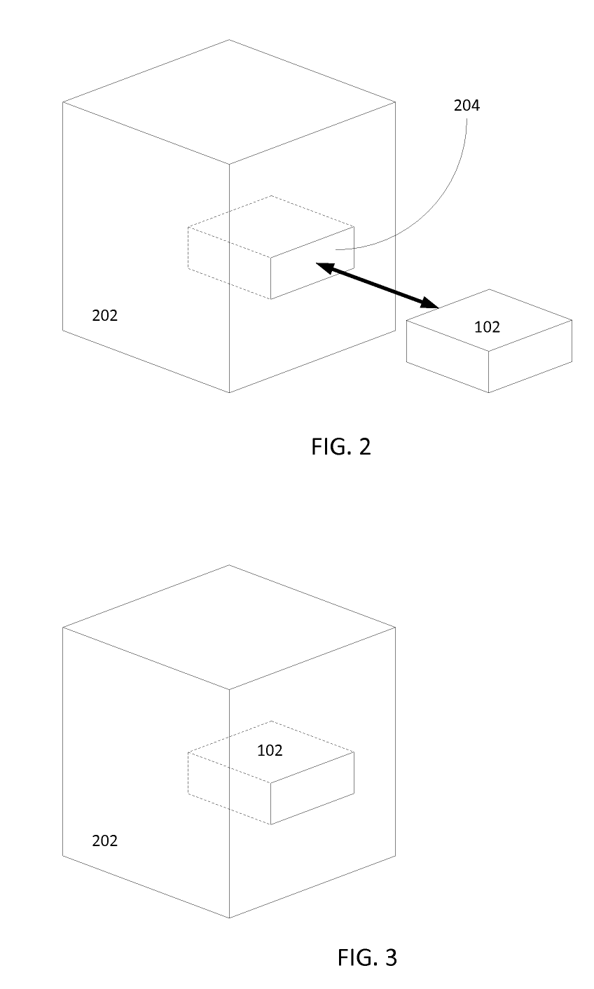

In various embodiments, the smart card device 102 may be arranged for insertion into any number of host devices. For example, as shown in FIG. 2, a host device may include an opening 204 in its enclosure to accommodate the smart card device 102. The host device 202 shown in FIG. 2 may be representative of a generic host device and is not intended to be limiting. More particularly, the host device 202 may be representative of any example host device described elsewhere herein and also of any host device not described herein as one skilled in the art will readily understand.

As shown in FIG. 3, the smart card device 102 may be fully inserted into the host device 202 in some embodiments. For example, the smart card device 102 may be arranged to be inserted into the opening 204 of the host device 202 such that an exposed edge of the smart card device 102 and the resulting side of the enclosure of the host device 202 form a smooth planar surface. In other embodiments (not shown), the smart card device 102 may be fully inserted into a host device. For example, a host device may include a compartment to house the smart card device 102 inside the enclosure of the host device. In other embodiments, the enclosure may include or comprise a cavity inside the enclosure to receive, support and substantially conceal the smart card device. In these embodiments, the cavity and/or compartment may be accessible by moving one or more components of the enclosure (e.g. sliding open a door or flap, lifting a spring closure, etc.). Other embodiments are described and claimed.

FIG. 4 illustrates a card device in a SD card form factor. Card device 102 (in FIG. 1) is enclosed within SD card form factor 404 in many embodiments. As shown, SD card form factor 404 includes a standard set of SD card contact pads (pads 400A-400H) as well as a standard set of SIM card contact pads (pads 402A-402H). For example, the set of SIM card contact pads also being present on the SD card form factor 404 allows for pin compatibility in a SIM socket (for given host devices that have that type of electrical pin out) in addition to pin compatibility in an SD socket. Apart from compatibility with multiple sockets, the SD card form factor 404 in FIG. can utilize the additional I/O pins for a broader range of I/O communication possibilities.

FIG. 5 illustrates a card device in a micro-SD card form factor. Relative sizes of cards between figures are not shown to scale. Card device 102 (in FIG. 1) is enclosed within micro-SD card form factor 504 in many embodiments. As shown, micro-SD card form factor 504 includes a standard set of micro-SD card contact pads (pads 500A-500H) as well as a standard set of SIM card contact pads (pads 502A-502H). In some embodiments, if a standard SIM card pin out does not fit on a given form factor card, the host device would be designed to make accommodations for the different physical size layout.

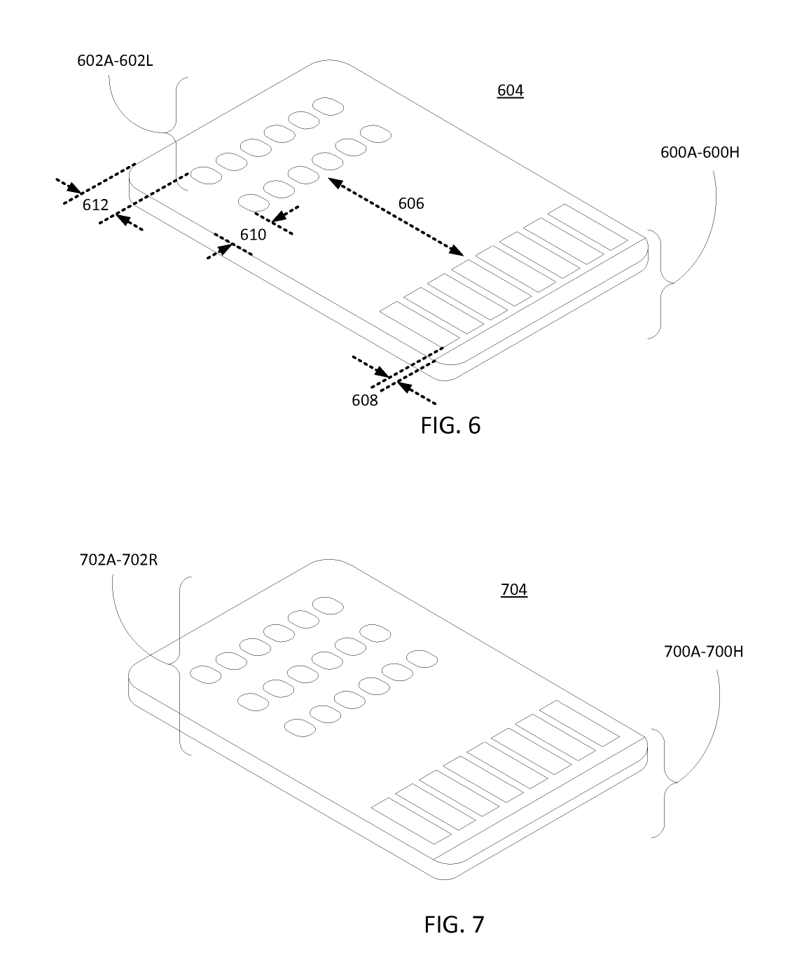

FIG. 6 illustrates a card device in a given card form factor. Card device 102 (in FIG. 1) is enclosed within card form factor 604 in many embodiments. In the embodiment shown, card form factor 604 includes a first set (i.e., group) of contact pads (pads 600A-600H) disposed at or substantially in a row at an edge of the card form factor 604 as well as a second set of contact pads (pads 602A-602L) disposed not at an edge of the card form factor 604, but more centralized in a group on one of the large sides of the card form factor 604. Additionally, the first set and second set of contact pads are shown as not being near each other (i.e. being substantially apart from each other), at least relative to the size and layout of the card form factor 604.

“Substantially” at an edge of the card refers to the first set of contact pads (600A-600H) being in a position where the edge of the card is close to the contact pads when referencing the size of the contact pads. In some embodiments, substantially at an edge may refer to the contact pads being within a distance (608 for example) from the edge that is less than the length of a contact pad. In other embodiments, substantially at an edge may refer to the contact pad being within a distance from the edge that is less than the width of a contact pad. In yet other embodiments, substantially at an edge may refer to the contact pad being within a distance from the edge that is less than a fraction of the width or length of the contact pad (e.g., ½, ¼, etc.).

On the other hand, “not substantially at an edge of the card” may refer to the second set of contact pads (602A-602L) being in a position where the edge of the card is far enough away from any position on a given contact pad in the second set so that the distance to the edge from the closest contact pad (610 and 612 for example) is more than the length and/or width of a contact pad in the group. In other embodiments, not substantially at the edge may refer to the distance from any position on a given contact pad in the second set is more than a multiple of the length and/or width of a contact pad in the group.

Furthermore, the first set of contact pads and the second set of contact pads in many embodiments are substantially separate from each other. In many embodiments, “substantially separate” may refer to the distance from any position on a given contact pad in the first set to the closest position of any contact pad in the second set is more than one length or width of a contact pad in the first or second group (or a multiple of the length and/or width of a contact pad in the first or second group). See distance 606 as an example. Substantially separate may be thought of as being significantly further and different than the distance between contact pads within the first set that are shown quite close to each other in the row (as seen in FIG. 6).

In many embodiments, these descriptions of distances between contact pads refer to standard pin out contact pad locations for SD cards, micro-SD cards, mini-SD cards, SIM cards, or one or more other cards that may be standardized or custom and may also refer any figure in the contact pad layout FIGS. 4-11.

FIG. 7 illustrates a card device in a given card form factor casing. Card device 102 (in FIG. 1) is enclosed within card form factor casing 704 in many embodiments. In the embodiment shown, card form factor casing 704 includes a first set of contact pads (pads 700A-700H) disposed substantially in a row at an edge of the card form factor casing 704 as well as a second set of contact pads (pads 702A-702R) disposed not at an edge of the card form factor casing 704, but more centralized in a group on one of the large sides of the card form factor casing 704. As shown in FIG. 6 and FIG. 7, the number of contact pads (pins) in each set is not limited to 8. In many other configurations there may be more than 8 pins per set. In some configurations there may be less than 8 pins per set as well.

FIG. 8 illustrates a card device in a given card form factor casing. Card device 102 (in FIG. 1) is enclosed within card form factor casing 806 in many embodiments. In the embodiment shown, card form factor casing 806 includes a first set of contact pads (pads 800A-800H) disposed substantially in a row at an edge of the card form factor casing 806 as well as a second set of contact pads (pads 802A-802H) disposed not at an edge of the card form factor casing 806, but more centralized in a group on one of the large sides of the card form factor casing 806. There is another group of contact pads (804A-804D) disposed on the opposite side of the card form factor casing 806 (shown in broken line). The opposite side is parallel to the first side of the casing in many embodiments. In this embodiment, there are contact pads on both large sides of the card form factor casing.

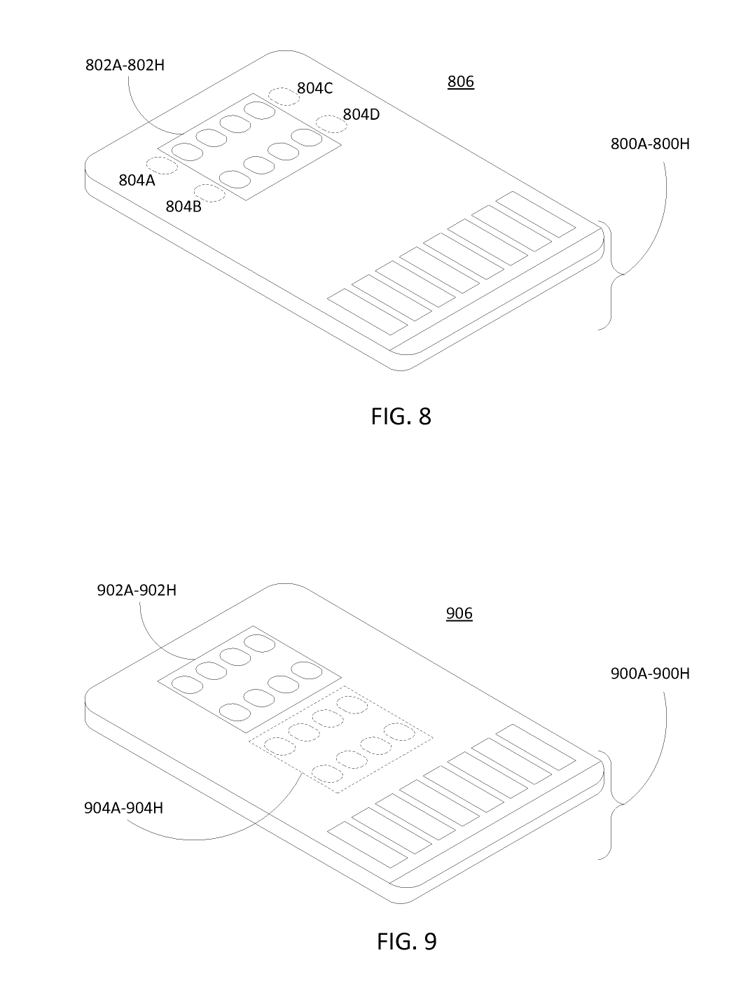

FIG. 9 illustrates a card device in a given card form factor casing. Card device 102 (in FIG. 1) is enclosed within card form factor casing 906 in many embodiments. In the embodiment shown, card form factor casing 906 includes a first set of contact pads (pads 900A-900H) disposed substantially in a row at an edge of the card form factor casing 906 as well as a second set of contact pads (pads 902A-902H) disposed not at an edge of the card form factor casing 906, but more centralized in a group on one of the large sides of the card form factor casing 906. There is a third group of contact pads, also not at the edge of the card (904A-904H) disposed on the opposite side of the card form factor casing 906 (shown in broken line). In this embodiment, there are contact pads on both large sides of the card form factor casing.

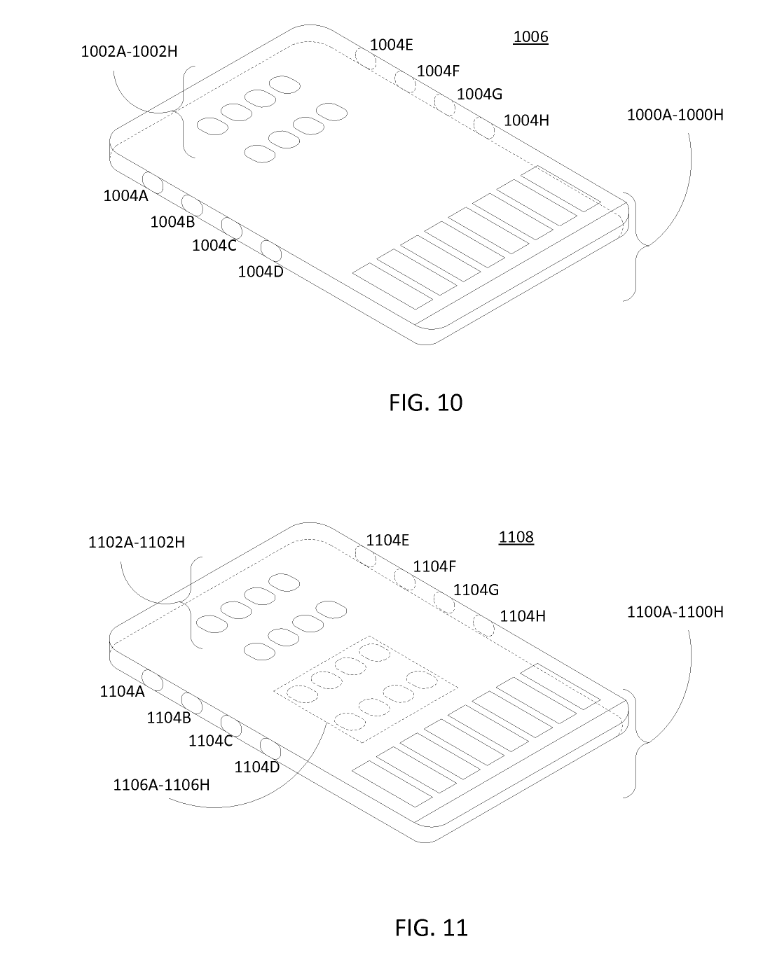

FIG. 10 illustrates a card device in a given card form factor casing. Card device 102 (in FIG. 1) is enclosed within card form factor casing 1006 in many embodiments. In the embodiment shown, card form factor casing 1006 includes a first set of contact pads (pads 1000A-1000H) disposed substantially in a row at an edge of the card form factor casing 1006 as well as a second set of contact pads (pads 1002A-1002H) disposed not at an edge of the card form factor casing 1006, but more centralized in a group on one of the large sides of the card form factor casing 1006. There is a third group of contact pads (1004A-1004H) disposed on two of the narrow sides of the card form factor casing 1006. The narrow sides of the card form factor casing are perpendicular to the large sides in many embodiments. In this embodiment, there are two sets of contact pads on one large sides of the card form factor casing 1006, and a set of contact pads split into two sub-groups on two of the narrow sides of the card form factor casing 1006.

FIG. 11 illustrates a card device in a given card form factor casing. Card device 102 (in FIG. 1) is enclosed within card form factor casing 1108 in many embodiments. In the embodiment shown, card form factor casing 1108 includes a first set of contact pads (pads 1100A-1100H) disposed substantially in a row at an edge of the card form factor casing 1108 as well as a second set of contact pads (pads 1102A-1102H) disposed not at an edge of the card form factor casing 1108, but more centralized in a group on one of the large sides of the card form factor casing 1108. There is third group of contact pads (1104A-1104H) disposed on two of the narrow sides of the card form factor casing 1108. There is a fourth group of contact pads, also not at the edge of the card(1106A-110611) disposed on the opposite side of the card form factor casing 1108 (shown in broken line). In this embodiment, there are two sets of contact pads on one of the large sides of the card form factor casing 1108, a set of contact pads on the other large side of the card form factor casing 1108, and a set of contact pads split into two sub-groups on two of the narrow sides of the card form factor casing 1108.

It should be appreciated that there can be any number of additional pin out/contact pad layouts for any number of card device form factors with one or more groups of pins on different areas of one or more sides of the card device.

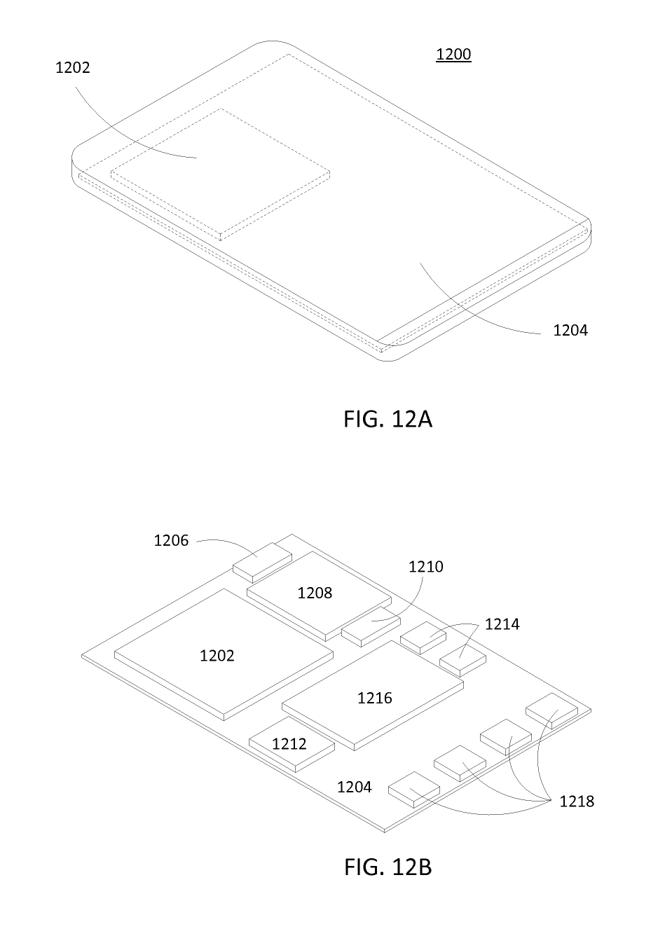

FIG. 12A illustrates a card device in a given card form factor casing. Card device 1204, which may include a circuit board, is enclosed within card form factor 1200 in many embodiments. In the embodiment shown, processor 1202 (e.g., processing logic) is soldered onto the circuit board of card device 1204 while it is encapsulated, at least partially within the form factor casing.

FIG. 12B illustrates a card device outside of the form factor casing and provides more details of some of the components that may also be included on the circuit board to which processor 1202 is attached. In some embodiments, one or more of a WiFi antenna module 1206, a WiFi control logic module 1208, a microphone 1210, an analog to digital (ADC) converter 1212, one or more oscillators 1214, a NAND flash module 1216, and one or more DC-to-DC converters/regulators 1218 are also attached to the circuit board with the processor 1202.

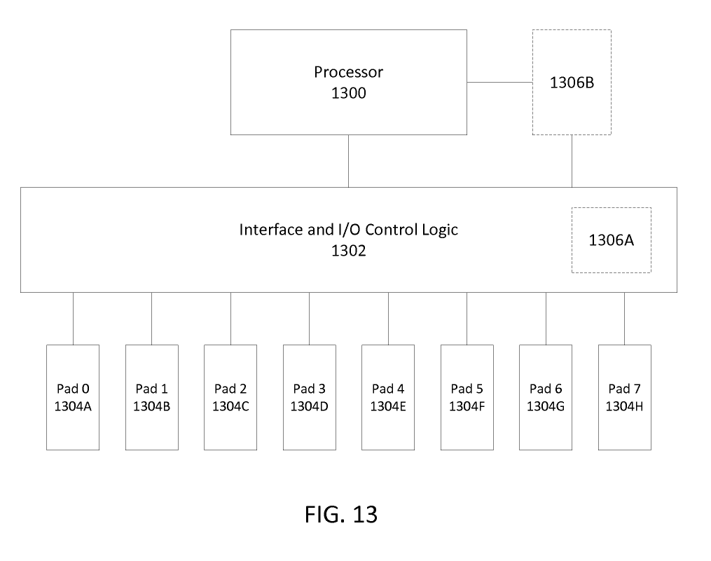

FIG. 13 illustrates an embodiment of a layout of the dynamic pin out (contact pad) configuration logic. In many embodiments, processing logic 1300 (e.g., a/the processor) is communicatively coupled to interface and I/O control logic (IICL) 1302. Being communicatively coupled includes any means where communication is possible between the two components. In some embodiments, one or more wire traces on a circuit board couple processing logic 1300 and IICL 1302. IICL 1302 has control of assigning each contact pad in the card device (such as pads 0-7 (1304A-1304H)) a specific pin definition. This definition may change upon inserting the card device into each host device. The pin configuration may include making a determination as to the configuration of the host device the card device is plugged into and then assigning pins/contact pads accordingly.

There are many ways to determine a given host device's pin configuration, including having a discovery protocol on one or more given pins, receiving the configuration wirelessly in advance, manually setting the configuration through a software algorithm, or one of a number of additional ways.

For example, one contact pad for the card device may always be present in a definition of the card device. Any host device that is compatible with the card device may provide pin configuration information upon request from the card device after first contact (at plug in). On the other hand, in other embodiments, a discovery protocol may be initiated on more than one pin if a given contact pad location is not determined so that any given pin/contact pad can provide discovery protocol information to the card device. Once the card device and the host device have discovered each other and exchanged pin information, the one or more pins utilized for discovery may be reconfigured to be used for standard I/O during normal operations.

In other embodiments, the pin configuration, being dynamic, may change during operations if the host device (or card device) requests a different set of services at different points in time. In these embodiments, the given contact pad/pin out definition may change one or more times for different purposes during the operation in the same card device/host device pairing. The discovery protocol or another rediscovery protocol may be utilized to implement this dynamic configuration update.

In some embodiments, logic that makes the contact pad/pin out definition determination may be hardware logic within the IICL 1302 (logic 1306A). In other embodiments, the logic making this determination may be software or firmware that is stored externally to the IICL 1302 (logic 1306B) and operated on by processing logic 1300 and/or IICL 1302.

Although many different pin outs/configurations may be utilized. Some of the contact pads/pins may be used for one or more of the following usages: universal asynchronous receiver/transmitter (UART) serial in/out pins, general purpose input/output (GPIO) pins, serial data switch (SDS) pins, inter integrated circuit (I2C) data and clock pins, reset pins, power supply pins (incoming from the host device and/or outgoing to the host device), serial peripheral interface (SPI) pins, general clock pins, etc.

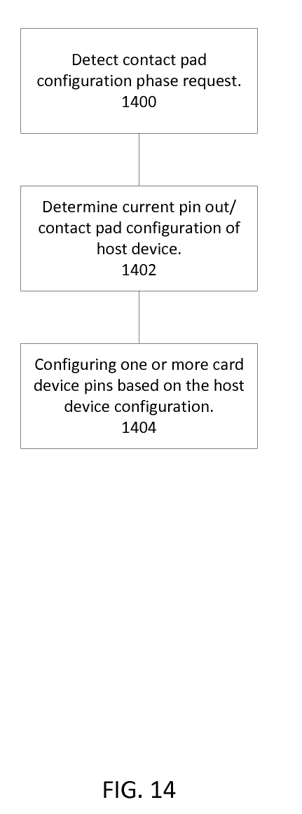

FIG. 14 illustrates a flow diagram of a dynamic contact pad discovery process. The process is performed by processing logic, which may be hardware, firmware, software, or a combination of two or more types of logic. The process begins by processing logic detecting a contact pad configuration phase request (processing block 1400). The configuration phase request may be internally generated by logic in the card device based on recognition of initial contact with the pins of the host device or an external request from the host device into which the card device is inserted.

The process continues with processing logic determining the current pin out/contact pad configuration of the host device (processing block 1402). The determination may be the result of receiving discovery data from the host device providing the definition of the pins/contact pads to align with internal card device pins.

The process completes with processing logic configuring/setting one or more card device pins to align with the host device pin out/contact pad layout and beginning operations (processing block 1404. In many embodiments, when not all pins/contact pads are utilized by the host device, the unused contact pads are disconnected (e.g., powered down).

Returning to FIG. 1, in various embodiments, the system 100 may comprise or include a combination or communicative coupling of a smart card device 102 and a host device 104. Stated differently, the smart card device 102 and the host device 104 may, separately, be inoperable or provide limited operability. This may be due to the lack of accessibility peripherals natively associated with the smart card device 102 and the lack of computing components natively associated with the host device 104. When a smart card device 102 is combined with any type of host device 104, however, the resulting computing system may be fully operations for the intended purpose. In various embodiments, the intended purpose may be dictated by the host device as described in more detail below.

As described above, the interface 120 and the host device interface may be arranged or configured to removably couple the smart card device 102 to the host device 104. In various embodiments, logic 110, at least a portion of which is in hardware, may be operative to configure the smart card device 102 based on one or more characteristics of the host device 104. For example, the logic 110 may detect a coupling of the smart card device 102 and the host device 104 and automatically configure one or more applications stored in a memory 108 of the smart card device 102 based on the one or more characteristics of the host device. In various embodiments, the application may comprise an application designed for use with a particular host device or a particular type of host device. For example, if the smart card device 102 is inserted into a smart watch host device, a watch and/or watch notification application may be automatically configured and/or executed to enable particular functionality associated with the smart watch host device. The embodiments are not limited in this respect.

In other embodiments, the logic 110 may detect a coupling of the smart card device 102 and the host device 104 and automatically download an application associated with the host device 104 based on the one or more characteristics of the host device 104. For example, if the smart card device 102 is inserted into a remote control host device, and the smart card device 102 does not currently have any applications or instructions associated with a remote control host device, the smart card device 102 may automatically download, install and execute a suitable application for use with the remote control host device. Other embodiments are described and claimed.

In various embodiments, configuration of the smart card device 102 based on one or more characteristics of the host device may comprise selecting a processor circuit 106A or 106B of the smart card device 102. For example, the characteristics of the host device may comprise, but are not limited to, one or more of an intended use of the host device, available I/O devices associated with the host device, size of the host device, shape of the host device, configuration of the I/O devices of the host device and the like. Based on any number of these characteristics, it may be advantageous to select one of the processors 106-1 or 106-2. In some embodiments, the processor circuit 106-1 may operative at a first frequency and may be used to execute a first operating system 112-1 while the processor circuit 106-2 may operate a second frequency (less than the frequency) and may execute a second operating system 112-2. In these embodiments, the logic 110 may automatically select one of the first preprocessor circuit 106-1 and first operating system 112-1 or second processor circuit 106-2 and second operating system 112-2 based on the one or more characteristics of the host device. The embodiments are not limited in this respect.

Included herein is a set of logic flows representative of example methodologies for performing novel aspects of the disclosed architecture. While, for purposes of simplicity of explanation, the one or more methodologies shown herein are shown and described as a series of acts, those skilled in the art will understand and appreciate that the methodologies are not limited by the order of acts. Some acts may, in accordance therewith, occur in a different order and/or concurrently with other acts from that shown and described herein. For example, those skilled in the art will understand and appreciate that a methodology could alternatively be represented as a series of interrelated states or events, such as in a state diagram. Moreover, not all acts illustrated in a methodology may be required for a novel implementation.

A logic flow may be implemented in software, firmware, and/or hardware. In software and firmware embodiments, a logic flow may be implemented by computer executable instructions stored on at least one non-transitory computer readable medium or machine readable medium, such as an optical, magnetic or semiconductor storage. The embodiments are not limited in this context

The various elements of the smart card device 102 and/or host device 104 as previously described with reference to the figures may comprise various hardware elements, software elements, or a combination of both. Examples of hardware elements may include devices, logic devices, components, processors, microprocessors, circuits, processors, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), memory units, logic gates, registers, semiconductor device, chips, microchips, chip sets, and so forth. Examples of software elements may include software components, programs, applications, computer programs, application programs, system programs, software development programs, machine programs, operating system software, middleware, firmware, software modules, routines, subroutines, functions, methods, procedures, software interfaces, application program interfaces (API), instruction sets, computing code, computer code, code segments, computer code segments, words, values, symbols, or any combination thereof. However, determining whether an embodiment is implemented using hardware elements and/or software elements may vary in accordance with any number of factors, such as desired computational rate, power levels, heat tolerances, processing cycle budget, input data rates, output data rates, memory resources, data bus speeds and other design or performance constraints, as desired for a given implementation.

The detailed disclosure now turns to providing examples that pertain to further embodiments. The examples provided below are intended to be exemplary and non-limiting.

In a first example, a card device, comprising a casing to enclose at least a portion of a processing logic, a first plurality of contact pads disposed substantially in a row near an edge of a first side of the casing, and a second plurality of contact pads disposed in a centralized group, the second plurality of contact pads substantially separate from the first plurality of contact pads.

In another example, a card device, comprising processing logic, a primarily rectangular-shaped casing having a first thickness to enclose the processing logic, a first plurality of contact pads disposed substantially in a row near an edge of an outwardly accessible first side of the casing, and a second plurality of contact pads disposed in a centralized group on another outwardly accessible portion of the casing, the second plurality of contact pads substantially separate from the first plurality of contact pads.

In another example, a card device wherein the second plurality of contact pads disposed substantially in one or more rows.

In another example, a card device wherein the second plurality of contact pads disposed not near an edge of the first side of the casing.

In another example, a card device wherein each of the first plurality of contact pads is of substantially equal length.

In another example, a card device wherein each contact pad in the second plurality of contact pads is separated from every contact pad in the first plurality of contact pads by a space at least equal to the length of a given contact pad in the first plurality of contact pads.

In another example, a card device wherein the second plurality of contact pads are disposed on the first side of the casing.

In another example, a card device wherein the second plurality of contact pads are disposed on a second side of the casing.

In another example, a card device wherein the second side of the casing adjoins the first side of the casing at a perpendicular angle.

In another example, a card device wherein the second side of the casing is parallel to the first side of the casing and wherein the second plurality of contact pads face in the opposite direction to the first plurality of contact pads.

In another example, a card device wherein the casing comprises a Secure Digital (SD) card casing.

In another example, a card device wherein a layout of the first plurality of contact pads on the casing comprises a SD card contact pad layout.

In another example, a card device wherein a layout of the second plurality of contact pads on the casing comprises a Subscriber Identity Module (SIM) card contact pad layout.

In another example, a card device wherein the casing comprises a micro-Secure Digital (SD) card casing.

In another example, an apparatus comprising a card device capable of being removably inserted into a host device, the card device to include a casing to enclose at least a portion of a processing logic, a first plurality of contact pads disposed substantially in a row near an edge of a first side of the casing, and a second plurality of contact pads disposed in a centralized group, the second plurality of contact pads substantially separate from the first plurality of contact pads, means for determining a configuration of a plurality of electrical contacts of an interface of the host device, and means for configuring a plurality of contact pads on the card device to allow for communication with the host device interface, wherein at least one of the plurality of contact pads to be in physical contact with at least one of the electrical contacts of the interface of the host device.

In another example, an apparatus wherein the second plurality of contact pads disposed substantially in one or more rows.

In another example, an apparatus wherein the second plurality of contact pads disposed not near an edge of the first side of the casing.

In another example, an apparatus wherein each of the first plurality of contact pads is of substantially equal length.

In another example, an apparatus wherein each contact pad in the second plurality of contact pads is separated from every contact pad in the first plurality of contact pads by a space at least equal to the length of a given contact pad in the first plurality of contact pads.

In another example, a method comprising determining a configuration of a plurality of electrical contacts of an interface of the host device, configuring a plurality of contact pads on a card device to allow for communication with the host device interface, wherein at least one of the plurality of contact pads to be in physical contact with at least one of the electrical contacts of the interface of the host device, and wherein the card device to include a casing to enclose at least a portion of a processing logic, a first plurality of contact pads disposed substantially in a row near an edge of a first side of the casing, and a second plurality of contact pads disposed in a centralized group, the second plurality of contact pads substantially separate from the first plurality of contact pads.

The foregoing examples and embodiments are set forth for purposes of illustration and not limitation. As such, other embodiments are described and claimed.

Some embodiments may be described using the expression “one embodiment” or “an embodiment” along with their derivatives. These terms mean that a particular feature, structure, or characteristic described in connection with the embodiment is included in at least one embodiment. The appearances of the phrase “in one embodiment” in various places in the specification are not necessarily all referring to the same embodiment. Further, some embodiments may be described using the expression “coupled” and “connected” along with their derivatives. These terms are not necessarily intended as synonyms for each other. For example, some embodiments may be described using the terms “connected” and/or “coupled” to indicate that two or more elements are in direct physical or electrical contact with each other. The term “coupled,” however, may also mean that two or more elements are not in direct contact with each other, but yet still co-operate or interact with each other.

It is emphasized that the Abstract of the Disclosure is provided to allow a reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separate embodiment. In the appended claims, the terms “including” and “in which” are used as the plain-English equivalents of the respective terms “comprising” and “wherein,” respectively. Moreover, the terms “first,” “second,” “third,” and so forth, are used merely as labels, and are not intended to impose numerical requirements on their objects.

What has been described above includes examples of the disclosed architecture. It is, of course, not possible to describe every conceivable combination of components and/or methodologies, but one of ordinary skill in the art may recognize that many further combinations and permutations are possible. Accordingly, the novel architecture is intended to embrace all such alterations, modifications and variations that fall within the spirit and scope of the appended claims.

1. A card device, comprising:
a casing to enclose at least a portion of a processing logic;
a first plurality of contact pads disposed substantially in a row near an edge of a first side of the casing; and
a second plurality of contact pads disposed in a centralized group, the second plurality of contact pads substantially separate from the first plurality of contact pads.

2. A card device, comprising:
processing logic;
a primarily rectangular-shaped casing having a first thickness to enclose the processing logic;
a first plurality of contact pads disposed substantially in a row near an edge of an outwardly accessible first side of the casing; and
a second plurality of contact pads disposed in a centralized group on another outwardly accessible portion of the casing, the second plurality of contact pads substantially separate from the first plurality of contact pads.

3. The card device of claim 1, wherein the second plurality of contact pads disposed substantially in one or more rows.

4. The card device of claim 1, wherein the second plurality of contact pads disposed not near an edge of the first side of the casing.

5. The card device of claim 1, wherein each of the first plurality of contact pads is of substantially equal length.

6. The card device of claim 5, wherein each contact pad in the second plurality of contact pads is separated from every contact pad in the first plurality of contact pads by a space at least equal to the length of a given contact pad in the first plurality of contact pads.

7. The card device of claim 1, wherein the second plurality of contact pads are disposed on the first side of the casing.

8. The card device of claim 1, wherein the second plurality of contact pads are disposed on a second side of the casing.

9. The card device of claim 8, wherein the second side of the casing adjoins the first side of the casing at a perpendicular angle.

10. The card device of claim 8, wherein the second side of the casing is parallel to the first side of the casing and wherein the second plurality of contact pads face in the opposite direction to the first plurality of contact pads.

11. The card device of claim 1, wherein the casing comprises a Secure Digital (SD) card casing.

12. The card device of claim 11, wherein a layout of the first plurality of contact pads on the casing comprises a SD card contact pad layout.

13. The card device of claim 11, wherein a layout of the second plurality of contact pads on the casing comprises a Subscriber Identity Module (SIM) card contact pad layout.

14. The card device of claim 1, wherein the casing comprises a micro-Secure Digital (SD) card casing.

15. An apparatus comprising:
a card device capable of being removably inserted into a host device, the card device to include:
a casing to enclose at least a portion of a processing logic;
a first plurality of contact pads disposed substantially in a row near an edge of a first side of the casing; and
a second plurality of contact pads disposed in a centralized group, the second plurality of contact pads substantially separate from the first plurality of contact pads;
means for determining a configuration of a plurality of electrical contacts of an interface of the host device; and
means for configuring a plurality of contact pads on the card device to allow for communication with the host device interface, wherein at least one of the plurality of contact pads to be in physical contact with at least one of the electrical contacts of the interface of the host device.

16. The apparatus of claim 15, wherein the second plurality of contact pads disposed substantially in one or more rows.

17. The apparatus of claim 15, wherein the second plurality of contact pads disposed not near an edge of the first side of the casing.

18. The apparatus of claim 15, wherein each of the first plurality of contact pads is of substantially equal length.

19. The apparatus of claim 18, wherein each contact pad in the second plurality of contact pads is separated from every contact pad in the first plurality of contact pads by a space at least equal to the length of a given contact pad in the first plurality of contact pads.

20. A method comprising:
determining a configuration of a plurality of electrical contacts of an interface of the host device;
configuring a plurality of contact pads on a card device to allow for communication with the host device interface, wherein at least one of the plurality of contact pads to be in physical contact with at least one of the electrical contacts of the interface of the host device; and
and wherein the card device to include a casing to enclose at least a portion of a processing logic, a first plurality of contact pads disposed substantially in a row near an edge of a first side of the casing, and a second plurality of contact pads disposed in a centralized group, the second plurality of contact pads substantially separate from the first plurality of contact pads.
